(19) United States
(12) Patent Application Publication
(10) Pub. No.: US 2016/0240761 A1
(43) Pub. Date: Aug. 18, 2016

(54) THERMOELECTRIC DEVICE

(71) Applicant: TDK CORPORATION, Tokyo (JP)

(72) Inventors: Kazuya MAEKAWA, Tokyo (JP); Takashi ASATANI, Tokyo (JP)

(73) Assignee: TDK CORPORATION, Tokyo (JP)

(21) Appl. No.: 15/018,024

(22) Filed: Feb. 8, 2016

(30) Foreign Application Priority Data
Feb. 16, 2015 (JP) 2015027362
Nov. 12, 2015 (JP) 2015221741

(51) Int. Cl. H01L 35/26; H01L 35/22

(52) U.S. Cl. CPC H01L 35/26; H01L 35/22

(57) ABSTRACT

A thermoelectric device includes a semiconductor stacked thin film including a SiGe layer and a Si layer in contact with the SiGe layer. The SiGe has a Si:Ge composition ratio by atomic number ratio within a range of 85:15 to 63:37. The stacked thin film has a plurality of stacked structures each having the SiGe layer and the Si layer.

### BACKGROUND OF THE INVENTION

1. Field of the Invention

The present invention relates to a thermoelectric device having thermoelectric properties.

2. Description of the Related Art

Thermoelectric devices utilizing thermoelectric properties of materials are investigated. Examples of a thermoelectric device using the Seebeck effect include a power-generating device utilizing a temperature difference between the outside air and human bodies, and a power-generating device utilizing waste heat from an automotive car, an incinerator, a heating device, or the like. Examples of a thermoelectric devices using the Peltier effect include cooling devices for CPU and a laser medium. In particular, the power generating device utilizing a temperature difference attracts attention as an energy harvesting component.

Thermoelectric devices which have been investigated are bulk-type devices using bulk materials such as bismuth-tellurium (BiTe)-based, lead-tellurium (PbTe)-based, silicide-based, or oxide-based materials, or the like. However, the bulk-type devices have very low power factor.

Japanese Unexamined Patent Application Publication No. 2000-244023 proposes, as a thermoelectric device using a thin film, a hetero-structure thermoelectric device including a carrier supply layer to which an additive is added and which has a predetermined band gap, and a high-purity layer which has a band gap smaller than that of the carrier supply layer. Also, silicon/silicon germanium (hereinafter referred to as “Si/SiGe”) is described as an example of the carrier supply layer/high-purity layer.

### SUMMARY OF THE INVENTION

However, even when a hetero-structure including two layers having different band gaps, such as Si/SiGe, is realized, it is difficult to actually realize a thermoelectric device having high power factor. An object of the present invention is to realize a thermoelectric device having high power factor.

The present invention relates to a thermoelectric device including a semiconductor stacked thin film including a SiGe layer and a Si layer in contact with the SiGe layer. The SiGe has a Si:Ge composition ratio by atomic number ratio within a range of 85:15 to 63:37. The stacked thin film has a plurality of stacked structures each having the SiGe layer and the Si layer.

The stacked structure causes lattice distortion in the Si layer due to a difference in lattice constant between the SiGe layer and the Si layer. The Si layer is improved in mobility of electrons and holes by the occurrence of lattice distortion. Thus, a high Seebeck coefficient and high electric conductivity can be realized, and the power factor of the thermoelectric device can be improved. Also, the stacked thin film has a plurality of stacked structures each having the SiGe layer and the Si layer, and thus high electric power can be easily obtained, for example, in application to thermoelectric power generation.

Further, the SiGe layer is preferably in contact with each of both surfaces of the Si layer.

Therefore, larger lattice distortion occurs in the Si layer by the effect of the SiGe layer in contact with each of both surfaces of the Si layer. Thus, mobility of electrons and holes can be improved, and the power factor of the thermoelectric device can be further improved.

Further, an additive of a group XIII element or group XV element is preferably added to at least one of the SiGe layers in the plurality of stacked structures.

In the stacked configuration, the addition of a specified element to the SiGe layer can increase electric conductivity while suppressing a decrease in Seebeck coefficient, and thus power factor of the thermoelectric device can be further improved.

Further, at least one of the rocking-curve half widths of a 0th order peak and satellite peaks thereof corresponding to the average lattice constant of the superlattice of the stacked thin film observed by X-ray diffraction measurement is preferably 0.1° or less. The stacked structure having such crystallinity can realize higher power factor.

Further, when the stacked thin film has crystallinity such that third or higher-order satellite peaks due to the superlattice of the stacked thin film are observed by X-ray diffraction measurement of the stacked thin film, even higher power factor can be realized.

Further, each of the Si layer and the SiGe layer preferably has a thickness of 1 nm or more and 10 nm or less. This can increase the electron density in each of the layers, realize even higher power factor, and suppress thermal conductivity.

According to the present invention, a thermoelectric device having higher power factor can be realized.

### BRIEF DESCRIPTION OF THE DRAWINGS

FIG. 1 is a cross-sectional view schematically showing a structure of a stacked thin film according to a first embodiment of the present invention.

FIG. 2 is a diagram showing the results and satellite peaks observed by X-ray diffraction measurement of the stacked thin film according to the first embodiment of the present invention.

FIG. 3 is a top view schematically showing a thermoelectric device according to the first embodiment of the present invention.

FIG. 4 is a cross-sectional view schematically showing the thermoelectric device according to the first embodiment of the present invention.

FIG. 5 is a cross-sectional view schematically showing a structure of a stacked thin film according to a second embodiment of the present invention.

FIG. 6 is a top view schematically showing a sample for evaluation of examples and comparative examples.

FIG. 7 is a cross-sectional view schematically showing a sample for evaluation of examples and comparative examples.

FIG. 8 is an explanatory view of an apparatus used for Seebeck measurement.

### DESCRIPTION OF THE PREFERRED EMBODIMENTS

Preferred embodiments of the present invention are described below with reference to the drawings. The present invention is not limited to the embodiments below. Also, components described below include components which can be easily conceived by the persons skilled in the art and substantially the same components as those components. Further, the components described below can be properly combined. Also, various omissions, substitutions, or changes of the components can be made without deviating from the scope of the gist of the present invention.

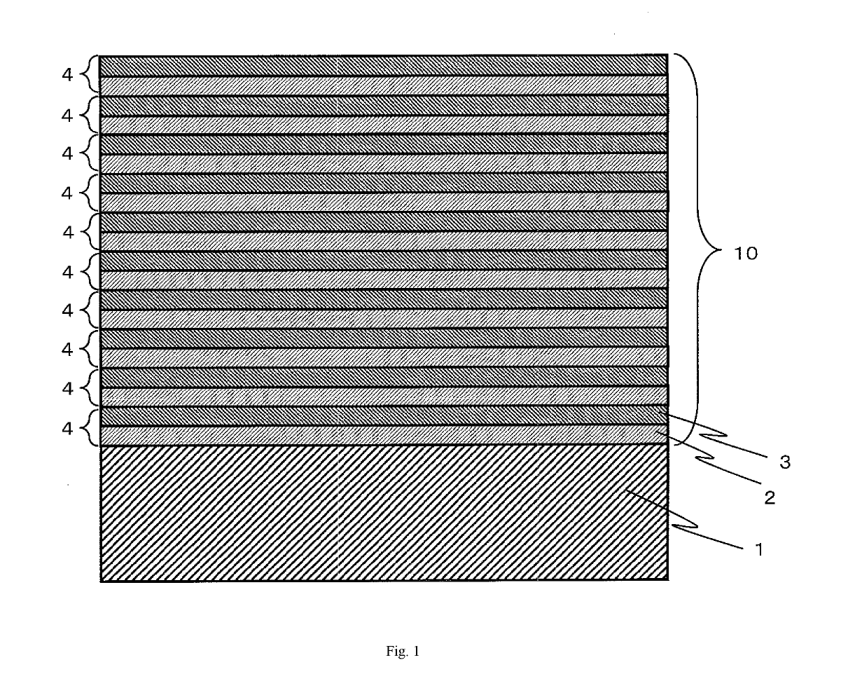

FIG. 1 is a cross-sectional view of a stacked thin film 10 according to a first embodiment. A thermoelectric device 14 of the embodiment includes the semiconductor stacked thin film 10 having a SiGe layer 2 and a Si layer 3 in contact with the SiGe layer 2, and the stacked thin film 10 has a plurality of stacked structures 4 each including the SiGe layer 2 and the Si layer 3. In the stacked thin film 10, the SiGe layer 2 is in contact with each of both surfaces of the Si layer 3. The stacked thin film 10 is formed on a (100) plane of a Si substrate 1. In FIG. 1, the number of the attacked structures 4 is 10 in order to make it easy to see. The SiGe layer 2 and the Si layer 3 are preferably alternately stacked to form multiple stacked layers. The number of the layers stacked is appropriately selected according to the purpose. In particular, multiple stacked layers are preferred for application to thermoelectric power generation because not only high electromotive force but also high electric power are required for application to thermoelectric power generation, and thus electric power can be easily drawn by stacking multiple layers.

In the first embodiment, the SiGe layer 2 is a P-type SiGe layer to which an additive of a group XIII element, such as B, Al, Ga, In, or Tl, is added or a N-type SiGe layer to which an additive of a group XV element, such as N, P, As, Sb, or Bi, is added. The SiGe layer 2 is a semiconductor layer and is imparted, by the additive, with the characteristics of a N-type semiconductor in which electrons function or a P-type semiconductor in which holes function.

Since the Si layer 3 is formed in contact with the SiGe layer having a larger lattice constant than Si, the Si layer 3 comes in a state (distorted Si) in which lattice distortion occurs. The composition ratio by atomic number ratio in the SiGe layer 2 is within a range of Si:Ge=85:15 to Si:Ge=63:37. With the composition ratio within the range, lattice distortion can be produced in the Si layer 3 without degrading crystallinity.

The composition ratio can be measured by energy dispersive X-ray spectrometry (referred to as “EDS” hereinafter) using a transmission electron microscope (referred to as “TEM” hereinafter). EDS can be used in accompanying TEM and is a method for detecting and analyzing the chemical composition of an object sample and evaluating the sample composition by irradiating elements constituting the object sample with electron beams and detecting the characteristic X-rays emitted from the elements.

In evaluation of the composition, EDS is combined with inductively coupled plasma mass spectrometry (referred to as “ICP-MS” hereinafter) with high measurement accuracy. ICP-MS is a method in which a sample solution is atomized by a nebulizer and introduced into plasma, and the elements in the introduced sample solution are ionized through desolvation, vaporization, and atomization steps, separated by ion lens convergence and a mass spectrometer in high vacuum, and measured and evaluated by a detector. In order to perform composition measurement with high accuracy, a reference sample having the same composition is previously measured by EDS and ICP-MS to form composition correlation data between the evaluation methods (the evaluation apparatuses), and a composition value is determined by using the data.

When the Si layer 3 is epitaxially grown in contact with the SiGe layer 2 or when the SiGe layer 2 is epitaxially grown in contact with the Si layer 3, tensile stress is applied to the Si layer 3 in an in-plane direction and compressive stress is applied to the Si layer 3 in a direction perpendicular to a plane based on a Poisson's ratio. A band structure is changed with a change in crystal structure, and a band at the conduction band edge/electron valence band edge which is degenerate in a distortion-less state is split. The conduction band is split into a two-fold degenerate band with light effective mass and a four-fold degenerate band. In the electron valence band, degeneration is solved into a heavy-hole band and a light-hole band. As a result, in a ground state, electrons are distributed in the two-hold degenerate band, and holes are distributed in the light-hole band. At the same time, particularly, anisotropy of heavy holes is decreased. Also, the electrons are distributed in the two-hold degenerate band with light effective mass, and the hole effective mass is decreased and hole scattering between the heavy-hole band and the light-hole band is decreased, thereby increasing the mobility of electrons and holes in an in-plane direction.

When each of the SiGe layer 2 and the Si layer 3 has a thickness of 1 nm or more, the effect of distortion can be sufficiently exhibited. When each of the SiGe layer 2 and the Si layer 3 has a thickness of less than 1 nm, the layer tends to be a discontinuous film, and the discontinuous film has a mosaic-shaped film interface and causes difficulty in satisfactorily achieving the effect of distortion. In order to satisfactorily achieve the effect of distortion, each of the SiGe layer 2 and the Si layer 3 preferably has a thickness of 1 nm or more and 50 nm or less.

A plurality of SiGe layers 2 in the stacked thin film 10 may have the same composition or some of the SiGe layers 2 may have different compositions as long as the SiGe layer 2 has a composition ratio by atomic number ratio within a range of Si:Ge=85:15 to Si:Ge=63:37.

In addition, the SiGe layer 2 and the Si layer 3 have a crystal structure having orientation in a specified plane orientation. The substrate 1 is a Si substrate with plane orientation (100) and functions to orient the thin film constituting the stacked thin film 10 in a specified plane orientation. In particular, a surface of the substrate 1 on which films are deposited preferably has clear plane orientation information.

In the embodiments, the expression “with specified plane orientation” represents being an epitaxial film, and the epitaxial film is first required to be a single-orientation film. In this case, the single-orientation film is a film showing a reflection peak with the maximum intensity on an intended plane as compared with reflection peak intensities on planes other than the intended plane in X-ray diffraction measurement. For example, a (00k) single-orientation film, that is, a c-plane singe-orientation film, shows a reflection peak with the maximum intensity on a (00k) plane as compared with reflection peak intensities on planes other than the (00k) plane in X-ray diffraction measurement of the film by a θ/2θ method. In addition, (00k) represents a general term of equivalent planes, such as (001), (002), and the like.

In the embodiments, a second condition for the epitaxial film is that when the in-plane is the x-y plane, and the thickness direction is the z-axis direction, the crystal is uniformly oriented in the x-axis direction, the y-axis direction, and the z-axis direction. Such orientation can be confirmed by a spot-like or streak-like sharp pattern in evaluation using both a transmission electron microscope and reflection high-energy electron diffraction. For example, when a deposited film having an irregular surface has disturbed crystal orientation, a reflection high-energy electron diffraction pattern tends to extend in a ring form, not has a sharp spot shape. When a film satisfies the two conditions described above, the film is considered as an epitaxial film.

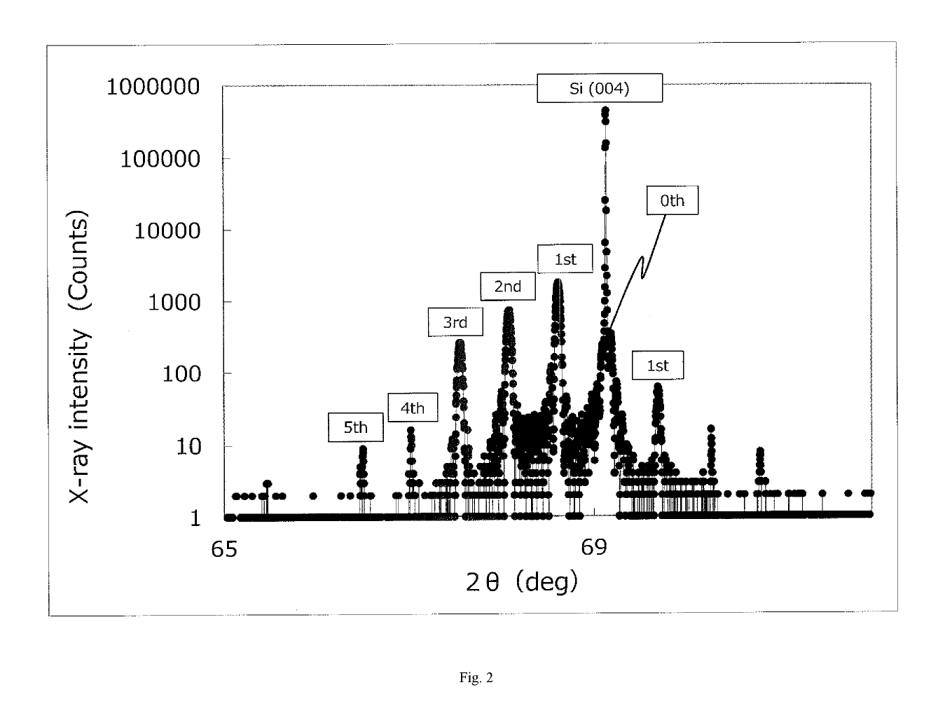

Since the stacked thin film 10 is a periodic film formed by stacking several times the stacked structure 4 of the SiGe layer 2 and the Si layer 3, characteristic satellite peaks are observed by X-ray diffraction measurement. Observation of the satellite peaks can confirm orientation and plane orientation. FIG. 2 is a diagram showing the satellite peak state obtained by plotting the results of X-ray diffraction measurement of the stacked thin film 10 by using a θ/2θ method. The θ/2θ method is a measurement method for X-ray diffraction in which an object is moved at intervals of θ and a detection side is moved at intervals of 2θ.

In FIG. 2, intensity peaks (orientation peaks) of a (004) orientation plane by X-diffraction of the Si substrate with plane orientation (100) are confirmed within a range of 69.1 to 69.2 (deg). However, satellite peaks due to interference and diffraction of a periodic film formed by stacking several times the stacked structure of the SiGe layer 2 and the Si layer 3 are observed around the (004) orientation peak of the Si substrate. The stacked thin film 10 forming a superlattice has two types of periods including the basic period of the crystal and a superlattice period longer than the basic period. Therefore, beside a peak corresponding to the basic period of the crystal, 0th-order peak and satellite peaks thereof corresponding to the average lattice constant of the superlattice appear in X-ray diffraction. Since the distance between the adjacent satellite peaks corresponds to the length of a reciprocal lattice with one superlattice period, information about the periodic structure can be obtained from the positions of the satellite peaks.

In the first embodiment, a 0th-order peak near the (004) orientation peak of Si and first-order, second-order, and third-order satellite peaks in order from the vicinity of the 0th-order peak are observed as satellite peaks, but third- or higher-order satellite peaks are preferably observed. In addition, when at least one of the rocking-curve half widths of the 0th-order peak and the satellite peaks observed by X-ray diffraction measurement is 0.1° or less, the epitaxial film is considered to have better crystallinity. Herein, the value of rocking-curve half width is described. The detection side is fixed at the angle of a peak detected by the θ/2θ method, and the object side is moved within a range of about ±1° to 3° of the angle θ to measure changes in the peak intensity. The rocking-curve half width is the angle width of a profile at a half of the maximum peak intensity. The smaller the half width, the more the crystal orientation is uniform.

The “power factor” is described below. A thermoelectric figure of merit Z is generally used as an index for evaluating a thermoelectric material, and Z is represented by formula 1 below, wherein S is a Seebeck coefficient, σ is electric conductivity, and κ is thermal conductivity.

Z=(S²σ/κ) (Formula 1)

In the formula 1, the product S²σ of the square of Seebeck coefficient S and electric conductivity σ is called “power factor”. As seen from the formula 1, in order to increase the value of thermoelectric figure of merit Z, it is also important to decrease the thermal conductivity κ.

According to industrial application examples, a value of power factor of 350 (μW/mK²) or more is preferred because it is considered to have a wider range of application as a thermoelectric device.

Each of the SiGe layer 2 and the Si layer 3 preferably has a thickness of 1 nm or more and 10 nm or less. The mean free path of electrons is 40 nm to 50 nm, and the thickness of 50 nm or less equal to or smaller than the mean free path of electrons can increase the electron density in these layers. Also, the mean free path of phonons is about 10 nm, and the thickness equal to or smaller than the mean free path of phonons can degrade thermal conduction due to lattice vibration of phonons and can suppress thermal conductivity. The SiGe layer 2 and the Si layer 3 each having a thickness of less than 1 nm tend to be a discontinuous film, and the discontinuous film has a mosaic-shaped film interface, causes an influence on electron scattering, and decreases the Seebeck coefficient and electric conductivity of each of the layers. The thickness over 50 nm causes difficulty in exhibiting an effect involving the mean free path of electrons, thereby decreasing the Seebeck coefficient and electric conductivity.

Therefore, when each of the SiGe layer 2 and the Si layer 3 preferably has a thickness of 1 nm or more and 10 nm or less, the Seebeck coefficient and electric conductivity can be increased, and thus high power factor can be achieved, and thermal conductivity can be suppressed.

The stacked thin film 10 is formed by depositing repeatedly 10 to 1000 times the stacked structures 4 of the SiGe layer 2 and the Si layer 3. The number of the structures stacked can be properly selected according to the purpose. For example, in application to thermoelectric power generation, the number of stacked structures is preferably 100 or more. The application to thermoelectric power generation requires not only high electromotive force but also high electric power, and thus electric power can be easily drawn by stacking 100 or more of the structures.

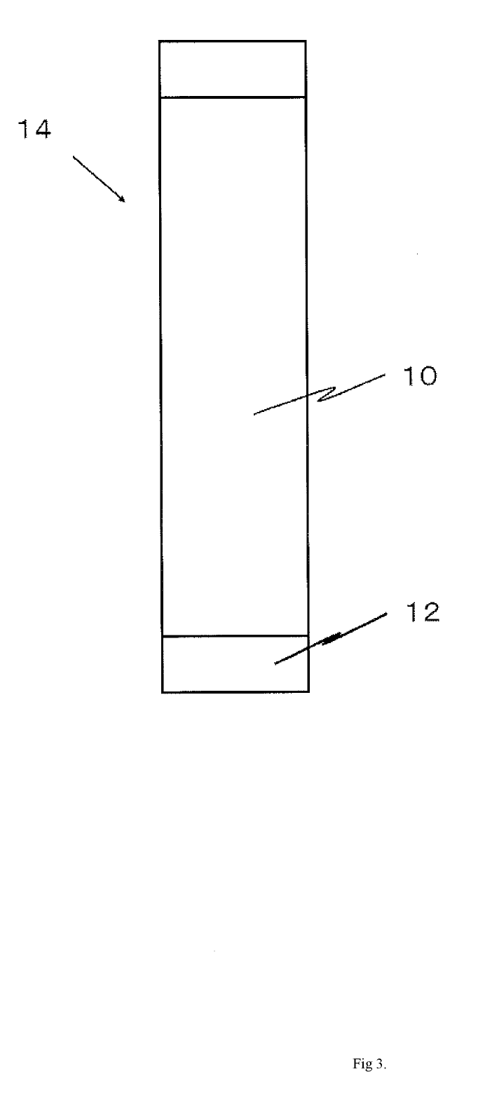

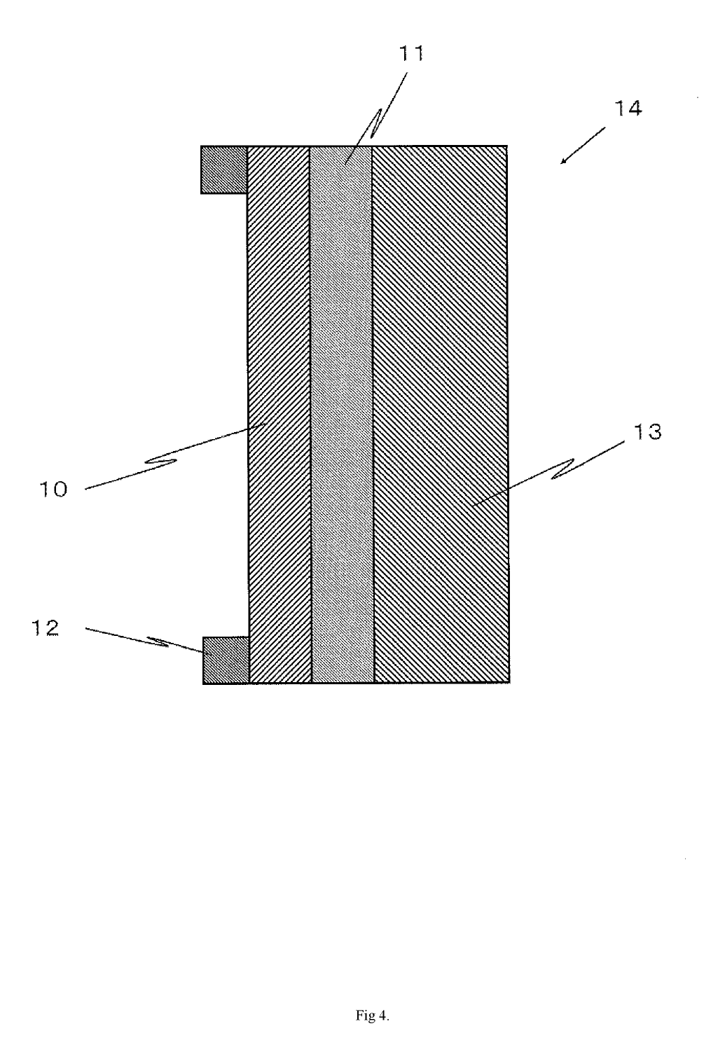

FIG. 3 is a top view of the thermoelectric device 14 with a rectangular parallelepiped shape provided with the stacked thin film 10, and FIG. 4 is a cross-sectional view of the thermoelectric device 14. The thermoelectric device 14 includes conductive terminals 12 provided at both ends of a surface of the stacked thin film 10, the substrate 1 being removed from the surface. Also, a protective material 13 is provided on the stacked thin film 10 through an adhesive layer 11. Therefore, the stacked thin film 10 can maintain strength and conductivity, and thus high rigidity as the thermoelectric device 14 can be obtained, that is, reliability can be achieved.

Next, the function of the thermoelectric device 14 is described.

The thermoelectric device 14 has the semiconductor stacked thin film 10 including the SiGe layer 2 and the Si layer 3 in contact with the SiGe layer 2, and the SiGe layer 2 has a Si:Ge composition ratio by atomic number ratio within a range of 85:15 to 63:37. Thus, lattice distortion occurs in the Si layer 3 due to a difference in lattice constant between the SiGe layer 2 and the Si layer 3. The Si layer 3 is improved in mobility of electrons and holes by the occurrence of lattice distortion. Thus, a large Seebeck coefficient and large electric conductivity can be realized, and the power factor of the thermoelectric device 14 can be improved. Also, the thermoelectric device 14 has a plurality of stacked structures 4 each having the SiGe layer 2 and the Si layer 3, and thus high electric power can be easily obtained, for example, in application to thermoelectric power generation.

The thermoelectric device 14 has a configuration in which the Si layer 3 having a large Seebeck coefficient is in contact with the SiGe layer 2 having higher electric conductivity and larger lattice constant than Si, the crystal structure of Si constituting the Si layer 3 is distorted, the energy band structure of the Si layer 3 is changed to improve carrier mobility, and the Seebeck coefficient and electric conductivity of the Si layer 3 are improved, thereby achieving high power factor S²σ. Also, SiGe is alloyed, and thus SiGe has the effect of increasing the thermoelectric figure of merit Z because of lower thermal conductivity than Si.

Further, the thermoelectric device 14 includes the SiGe layer 2 in contact with each of both surfaces of the Si layer 3. Therefore, larger lattice distortion occurs in the Si layer 3 by the effect of the SiGe layer 2 in contact with each of both surfaces of the Si layer 3. Thus, mobility of electrons and holes can be improved, and the power factor can be further improved.

Further, in the thermoelectric device 14, an additive of a group XIII element or group XV element is added to at least one of the SiGe layers 2 in the plurality of stacked structures 4, and thus electric conductivity can be increased while suppressing a decrease in the Seebeck coefficient, thereby further improving the power factor.

With respect to the additive to the SiGe layer 2, the electric conductivity can be easily increased by increasing the amount of additive added, but the Seebeck coefficient tends to be decreased. The amount of the additive is preferably within a range of 0.0001 to 0.1 atomic % relative to SiGe. This range can maintain the power factor value high.

Further, in the thermoelectric device 14, at least one of the rocking-curve half widths of a 0th order peak and satellite peaks thereof corresponding to the average lattice constant of the superlattice of the stacked thin film 10 observed by X-ray diffraction measurement is preferably 0.1° or less. The stacked structure having such crystallinity can realize higher power factor.

Further, when the stacked thin film 10 in the thermoelectric device 14 has crystallinity such that third or higher-order satellite peaks due to the superlattice of the stacked thin film 10 are observed by X-ray diffraction measurement of the stacked thin film 10, even higher power factor can be realized.

Further, in the thermoelectric device 14, each of the Si layer 3 and the SiGe layer 2 preferably has a thickness of 1 nm or more and 10 nm or less. This can increase the electron density in each of the layers and increase the Seebeck coefficient and electric conductivity, and thus even higher power factor can be achieved, and thermal conductivity can be suppressed.

The thermoelectric device 14 of this embodiment has higher power factor S²σ than usual thermoelectric devices. Therefore, the thermoelectric device 14 capable of producing high output with a small number of elements joined can be produced, thereby permitting miniaturization of an apparatus and modularization.

Next, a second embodiment of the present invention is described.

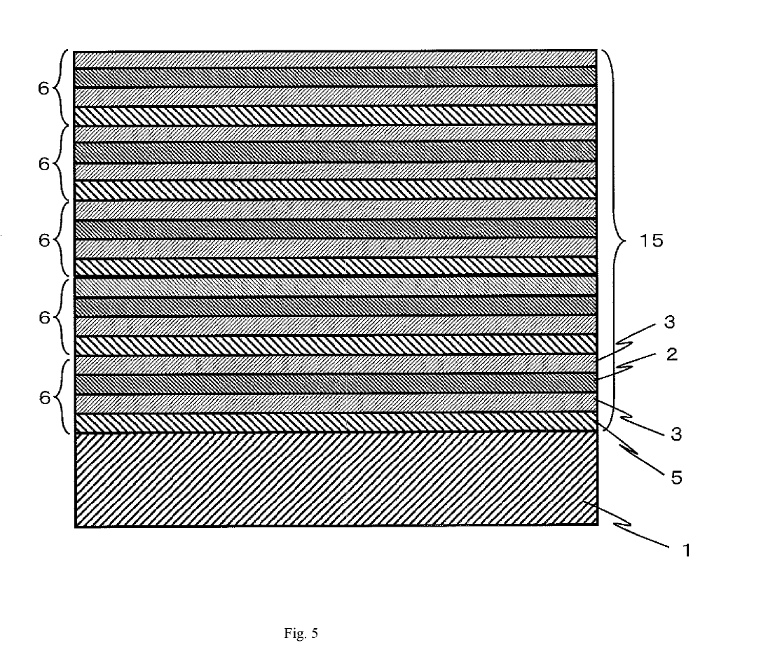

FIG. 5 is a cross-sectional view of a stacked thin film 15 according to the second embodiment. The stacked thin film 15 according to the second embodiment includes, in addition to the stacked thin film 10 according to the first embodiment, an undoped SiGe layer 5 which is a SiGe layer not containing an additive added thereto. The stacked thin film 15 includes a plurality of stacked structures 6 each having a Si layer 3 stacked on the undoped SiGe layer 5, a SiGe layer 2 formed on the Si layer 3, and a Si layer 3 further formed on the SiGe layer 2. FIG. 5 shows five stacked structures 6 in order to make it easy to see. The stacked structure 6 is preferably stacked multiple times. The number of the structures 6 stacked is appropriately selected according to the purpose. In particular, multiple stacked layers are preferred for application to thermoelectric power generation.

Also, in the second embodiments, a high power factor can be obtained by the same function as in the first embodiment. Like in the SiGe layer 2, the thickness of the undoped SiGe layer 5 is preferably 1 nm or more and 50 nm or less in order to achieve the satisfactory effect of distortion. Also, like in the SiGe layer 2, the thickness of the undoped SiGe layer 5 is more preferably 1 nm or more and 10 nm or less because a higher power factor can be obtained.

In the first embodiment, the SiGe layer 2 is a P-type SiGe layer to which an additive of a group XIII element, such as B, Al, Ga, In, or Tl, is added or a N-type SiGe layer to which an additive of a group XV element, such as N, P, As, Sb, or Bi, is added. However, an undoped SiGe layer to which an additive is not added may be used as some or all of the SiGe layers 2 in the plurality of stacked structures 4.

In addition, in the second embodiment, the stacked structure 6 has a configuration in which the undoped SiGe layer 5, the Si layer 3, the SiGe layer 2, and the Si layer 3 are stacked in that order, but the order of stacking is not particularly limited. For example, the stacked structure 6 may have a configuration in which the SiGe layer 2, the Si layer 3, the undoped SiGe layer 5, and the Si layer 3 are stacked in that order.

### (Manufacturing Method)

A method for manufacturing the thermoelectric device 14 according to the embodiment is described below. A method for producing the first SiGe layer 2 and the Si layer 3 is not particularly limited, and various film forming methods can be properly used. Examples of a physical vapor deposition method which can be used include resistance-heating vapor deposition, electron beam vapor deposition, molecular beam epitaxy, ion plating, ion beam deposition, sputtering, and the like. Examples of a chemical vapor deposition method (hereinafter referred to as “CVD”) which can be used include thermal CVD, optical CVD, plasma CVD, epitaxial CVD, atomic layer CVD, MO (metal organic)-CVD, and the like.

The substrate 1 is preferably previously subjected to surface treatment before film deposition. The substrate 1 is surface-treated by, for example, washing at a high temperature with a concentrated liquid prepared by adding an alkali or acid to a hydrogen peroxide base and then washing with hydrofluoric acid.

The washed substrate 1 is subjected to film deposition. The temperature of the substrate is adjusted for epitaxially growing the stacked thin film 10 on the substrate 1.

The SiGe layers 2 and the Si layers 3 are properly alternately deposited in a necessary number of layers on the substrate 1. In this case, the deposition rate of each of the materials is measured in advance, and the layers are alternately deposited by a time management method.

When the stacked thin film 10 is epitaxially grown, the thin film 10 is formed with a certain orientation relation on the substrate 1 used. Therefore, the film formation orientation of the stacked thin film 10 from the substrate 1 can be confirmed by a transmission electron microscope. Also, when the stacked thin film 10 is a periodic film formed by stacking several times the stacked structure 4 of the SiGe layer 2 and the Si layer 3, characteristic satellite peaks are observed in X-ray diffraction measurement.

As shown in FIG. 4, the protective material 13 is provided, through the adhesive layer 11, on the stacked thin film 10 deposited as described above. In this stage, a configuration including the substrate 1, the stacked thin film 10, the adhesive layer 11, and the protective material 13 is formed. Examples of the protective material 13 which can be used include ceramics such as alumina, silica, zirconia, and magnesia; materials with relatively high resistance, such as quartz glass, borosilicate glass, germanium glass, sapphire glass, crystalline glass, low-expansion glass, soda glass, heat-resistant glass, high-resistance Si and the like. The material is appropriately selected according to compatibility with the stacked thin film 10 and the temperature of the actual device used. The adhesive material used for the adhesive layer 11 is, for example, an epoxy material.

A method for forming the protective material 13 can be properly selected from various methods such as anodic bonding, room-temperature bonding, ultrasonic bonding, and the like. The method can be properly selected so that satisfactory adhesive strength to the material of the stacked thin film 10 can be obtained. When a method for bonding without using an adhesive material is selected, the adhesive layer 11 is not required.

Next, the substrate 1 is removed from the structure including the substrate 1, the stacked thin film 10, the adhesive layer 11, and the protective material 13.

A chemical removal method or mechanical removal method can be properly used as a method for removing the substrate 1. In this embodiment, the substrate 1 is removed by wet or dry etching. For example, when the substrate 1 is a Si single crystal, immersion in an alkali aqueous solution can be performed as a wet etching method. The alkali aqueous solution is preferably a 10-50% aqueous solution of potassium hydroxide (KOH), sodium hydroxide (NaOH), an ammonia-based compound (TMAH, tetramethylammonium hydroxide), or the like. Only the substrate 1 is removed by immersing the structure including the substrate 1, the stacked thin film 10, the adhesive layer 11, and the protective material 13 in the aqueous solution. In this case, the periphery may be coated with a resin or the like in order to protect the stacked thin film 10. The etching rate of the substrate 1 is measured in advance, and only the substrate 1 is removed by etching under time management.

On the other hand, the dry etching method is preferably performed by using an ion beam etching apparatus or reactive ion etching apparatus provided with a secondary ion mass spectrometry and having the function that an etching end point can be detected. For example, Ge of the SiGe layer 2 is regarded as a detection element, and the time when Ge is detected is regarded as the etching end point. Even when wet etching is used, the substrate 1 is under-etched to leave the substrate 1 in order to prevent over-etching and then the remaining substrate 1 is removed by dry etching, thereby permitting precise removal of the substrate 1. The wet etching tends to cause a high etching rate with little damage, while the dry etching tends to cause high precision of end point detection. A combination of wet etching and dry etching tends to enable the rapid work of removing the substrate with high precision.

A coarse grinding step may be provided as a pre-step of etching treatment. For example, the substrate 1 is subjected to vertical grinding by abrasive grinding, CMP grinding with colloidal silica, or diamond slurry grinding with a soft metal plate such as a tin surface plate or the like, and then the substrate 1 may be removed by etching treatment.

Next, the formation of the conductive terminals 12 is described. The structure including the stacked thermoelectric thin film 10, the adhesive layer 11, and the protective material 13 resulted by removing the substrate 1 is further surface-protected (not shown). The surface protection can be performed by bonding a plastic film material or the like. After the surface protection, the resultant structure including the stacked thermoelectric thin film 10, the adhesive layer 11, and the protective material 13 is cut into a desired size.

Next, resist is applied to the structure including the stacked thermoelectric thin film 10, the adhesive layer 11, and the protective material 13. The viscosity of the resist and the rotational speed of a spinner are adjusted so that the thickness is about 1 to 3 μm. Then, resist holes are formed in the resist in order to form the conductive terminals 12 at the ends of the material of the stacked thermoelectric thin film 10.

Next, a low-resistance metal such as Au/Ti, Pt, Cu, Al, or an alloy thereof is deposited as a material of the conductive terminals 12. The thickness of the metal deposited is generally about 100 to 500 nm. Then, the resist is removed with a solvent. Washing with the solvent may be further performed for avoiding the residue of the resist. When the formation of the conductive terminals 12 is completed, a sample piece is separated from a jig. As described above, the thermoelectric device 14 with the conductive terminals 12 is completed as shown in FIGS. 3 and 4.

### EXAMPLES

Typical examples of the stacked thin films 10 and 15 and the thermoelectric device 14 according to the present invention are described with reference to examples and comparative examples.

### Example 1

In Example 1, a N-type sample exclusive for thermoelectric evaluation was formed and evaluated, in which the sample had characteristics equivalent to those of the thermoelectric device 14 including the stacked thin film 10 according to the first embodiment, and the SiGe layer 2 was doped with Sb. First, the stacked thin film 10 was formed on the substrate 1.

A single-crystal Si substrate was prepared as the substrate 1. The (100) plane of the substrate 1 was used as a deposition surface. The substrate 1 was washed at a high temperature with a concentrated liquid prepared by adding an alkali or acid to a hydrogen peroxide base and then washed with hydrofluoric acid.

The stacked thin film 10 was formed on the washed substrate 1. First, the Sb-doped SiGe layer 2 was formed. The thickness of the SiGe layer 2 was 10 nm. The Si:Ge composition ratio by atomic number ratio in the SiGe layer 2 was 70:30. Sb was added at the same time as the deposition. The amount of Sb added was 0.001 atomic % based on SiGe.

Then, the Si layer 3 was formed to 10 nm. The SiGe layer 2 and the Si layer 3 were deposited repeatedly 10 times, thereby forming the stacked thin film 10 including multiple layers formed by stacking 10 times the SiGe layer 2 and the Si layer 3.

### Example 2

In Example 2, the Si:Ge composition ratio by atomic number ratio in the SiGe layer 2 of Example 1 was changed to 85:15. Excepting the composition ratio, Example 2 was the same as Example 1.

### Example 3

In Example 3, the Si:Ge composition ratio by atomic number ratio in the SiGe layer 2 of Example 1 was changed to 63:37. Excepting the composition ratio, Example 3 was the same as Example 1.

### Example 4

Although, in Example 1, the SiGe layer 2 was formed by adding Sb to SiGe, in Example 4, a P-type sample exclusive for thermoelectric evaluation was formed and evaluated by using B in place of Sb. Excepting the additive, Example 4 was the same as Example 1.

### Example 5

Although, in Example 2, the SiGe layer 2 was formed by adding Sb to SiGe, in Example 5, a P-type sample exclusive for thermoelectric evaluation was formed and evaluated by using B in place of Sb. Excepting the additive, Example 5 was the same as Example 2.

### Example 6

Although, in Example 3, the SiGe layer 2 was formed by adding Sb to SiGe, in Example 6, a P-type sample exclusive for thermoelectric evaluation was formed and evaluated by using B in place of Sb. Excepting the additive, Example 6 was the same as Example 3.

### Comparative Example 1

In Comparative Example 1, the same stacked thin film as in Example 1 was formed except that the Si:Ge composition ratio by atomic number ratio in the SiGe layer 2 of Example 1 was changed to 86:14.

### Comparative Example 2

In Comparative Example 2, the same stacked thin film as in Example 1 was formed except that the Si:Ge composition ratio by atomic number ratio in the SiGe layer 2 of Example 1 was changed to 62:38.

### Comparative Example 3

In Comparative Example 3, the same stacked thin film as in Example 4 was formed except that the Si:Ge composition ratio by atomic number ratio in the SiGe layer 2 of Example 4 was changed to 86:14.

### Comparative Example 4

In Comparative Example 4, the same stacked thin film as in Example 4 was formed except that the Si:Ge composition ratio by atomic number ratio in the SiGe layer 2 of Example 4 was changed to 62:38.

### (Formation of Sample for Evaluation)

A sample was formed for evaluating the stacked thin film of each of the examples and the comparative examples.

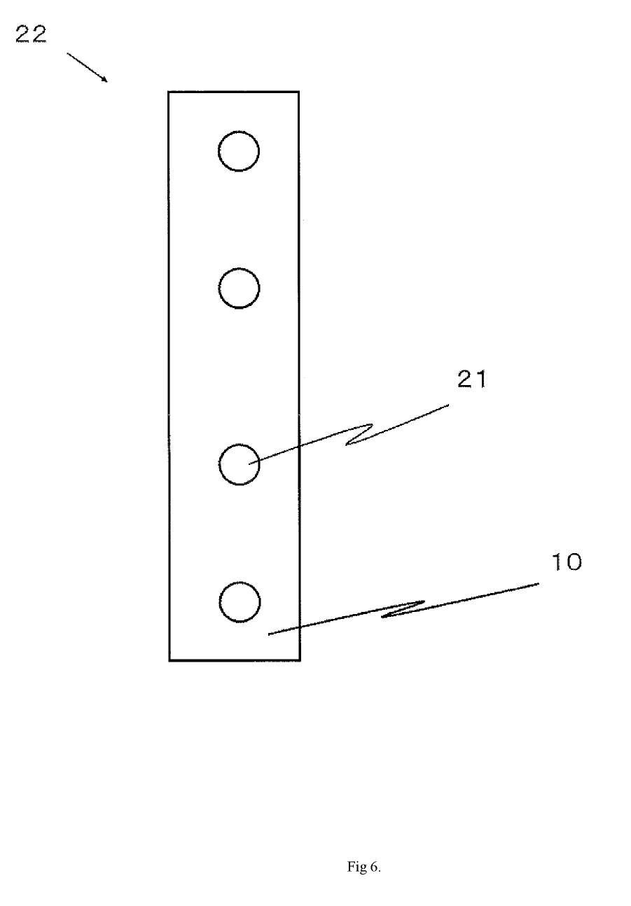

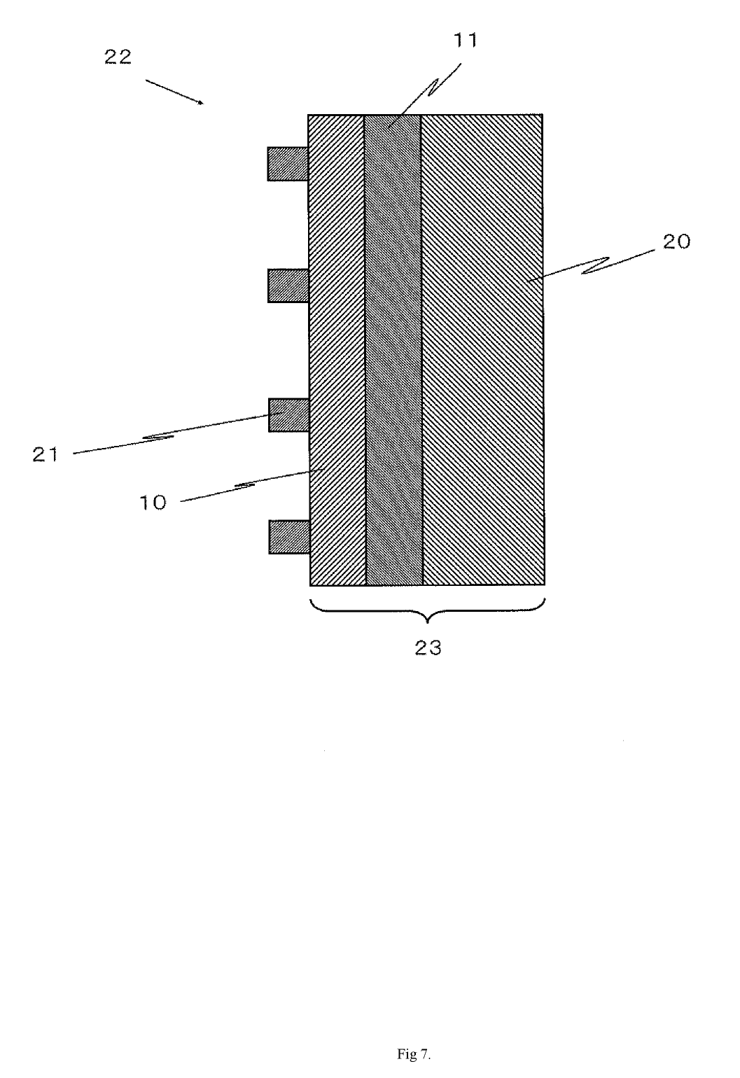

FIG. 6 is a top view of a strip-shaped sample 22 for evaluation of the examples and the comparative examples, and FIG. 7 is a cross-sectional view of the sample 22. A method for forming the sample 22 for evaluation is described below.

An adhesive layer 11 including an adhesive resin film was applied by a spin coating method to the stacked thin film 10 deposited on the Si substrate. Then, an alumina substrate 20 having the same size as the single-crystal Si substrate was bonded as a protective material through the adhesive layer 11. Then, the adhesive resin film was cured by a heat curing method under pressure to form a stack 23.

Next, the single-crystal Si substrate was removed, and the stack 23 including the stacked thin film 10, the adhesive layer 11, and the alumina substrate 20 was cut. The resultant stack 23 was cut by using a dicer having an edge thickness of 60 μm. The cut stack 23 was a strip-shaped sample of 20 mm in length and 4 mm in width.

Next, as shown in FIG. 6, platinum electrodes 21 having a diameter of 1 mm and a thickness of 100 nm were formed on the strip-shaped sample 22 for evaluation.

### (Measurement of Seebeck Coefficient)

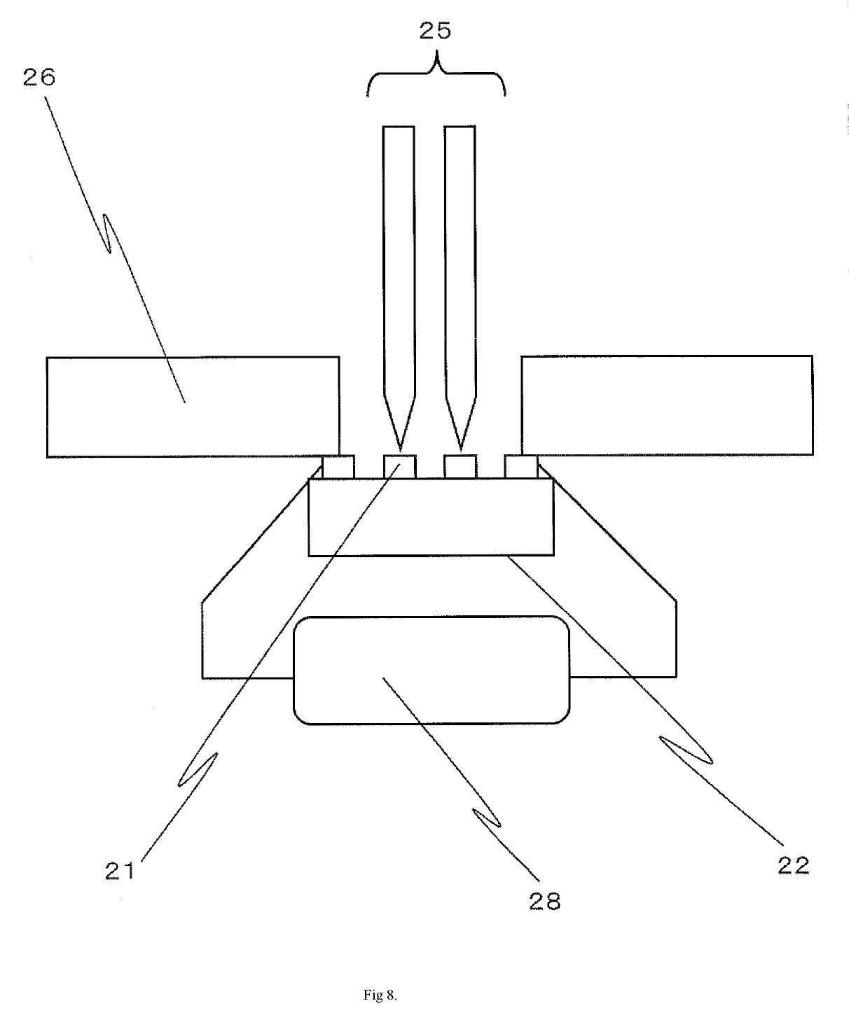

The Seebeck coefficient of the completed sample 22 for evaluation was measured. FIG. 8 is a drawing illustrating a configuration of an apparatus for Seebeck measurement. A measurement method is schematically shown in FIG. 8. The measurement was performed in a constant-temperature oven heated and kept at 50° C. Electric conductivity of the sample 22 for evaluation was measured by passing, from a constant-current source 28, a constant current (0.15 mA) between the two outer platinum electrodes 21 formed on the surface of the sample 22 for evaluation, placing thermocouple probes 25 between the two inner platinum electrodes 21 of the sample 22 for evaluation, and measuring voltage dV between the thermocouple probes 25. The Seebeck coefficient was measured by placing a block heater 26 in contact with each of the two outer platinum electrodes 21 formed on the surface of the sample 22 for evaluation to provide a temperature gradient of 5 degrees/8 mm in the longitudinal direction of the sample 22 for evaluation, placing the thermocouple probes 25 between the two inner electrodes 21 of the sample 22 for evaluation, and measuring thermoelectromotive force dE.

Table 1 shows the values of rocking-curve half widths of the 0th peak and satellite peaks observed in X-ray diffraction measurement of the stacked thermoelectric thin films of the examples and the comparative examples. Table 1 also shows the results of calculation of the values of power factor S²σ from the Seebeck coefficient S and electric conductivity σ measured for the samples for evaluation of the examples and the comparative examples. Table 1 further shows the a-axis and c-axis lattice constants of the Si layers 3 and the a-axis and c-axis distortion factors of the Si layers 3 determined by X-ray diffraction measurement.

The lattice distortion factors of the Si layer 3 of each of the stacked thin films 10 are calculated by using the measurement values of a-axis lattice constant and c-axis lattice constant obtained by XRD measurement according to formulae below wherein Xa is the a-axis lattice constant and Zc is the c-axis lattice constant of undistorted Si.

a-axis distortion factor=(Xa−a-axis lattice constant measurement value)/Xa/100[%] (Formula 2)

c-axis distortion factor=(Zc−c-axis lattice constant measurement value)/Zc/100[%] (Formula 3)

TABLE 1

| | | | | | | | Lattice constant of Si layer | | | |
|---|---|---|---|---|---|---|---|---|---|---|
| | | | Satellite peak | | | Power | | | a-axis | c-axis |
| | | 0th | First | Second | Third | factor | a axis | c axis | distortion | distortion |
| | | order | order | order | order | (μW/mK²) | (nm) | (nm) | factor (%) | factor (%) |
| Example 1 | 2θ (deg) | 69.4 | 68.6 | 68.3 | 67.6 | 498 | 0.550 | 0.536 | −1.252 | 1.234 |
| | Rocking-curve | 0.0076 | 0.0237 | 0.0228 | 0.0223 | | | | | |
| | half width (deg) | | | | | | | | | |
| Example 2 | 2θ (deg) | 69.1 | 68.4 | 68.1 | 67.4 | 385 | 0.544 | 0.542 | −0.184 | 0.184 |
| | Rocking-curve | 0.0075 | 0.0232 | 0.0222 | 0.0213 | | | | | |
| | half width (deg) | | | | | | | | | |
| Example 3 | 2θ (deg) | 69.8 | 68.8 | 68.5 | 67.8 | 465 | 0.552 | 0.534 | −1.621 | 1.602 |
| | Rocking-curve | 0.0078 | 0.0243 | 0.0235 | 0.0234 | | | | | |
| | half width (deg) | | | | | | | | | |
| Example 4 | 2θ (deg) | 69.5 | 68.7 | 68.4 | 67.6 | 505 | 0.550 | 0.536 | −1.271 | 1.252 |
| | Rocking-curve | 0.0078 | 0.0468 | 0.0679 | 0.0881 | | | | | |
| | half width (deg) | | | | | | | | | |
| Example 5 | 2θ (deg) | 69.1 | 68.4 | 68.1 | 67.4 | 392 | 0.544 | 0.542 | −0.188 | 0.182 |
| | Rocking-curve | 0.0077 | 0.0465 | 0.0576 | 0.0877 | | | | | |
| | half width (deg) | | | | | | | | | |
| Example 6 | 2θ (deg) | 69.8 | 68.8 | 68.5 | 67.8 | 476 | 0.552 | 0.534 | −1.584 | 1.584 |
| | Rocking-curve | 0.0079 | 0.0478 | 0.0676 | 0.0986 | | | | | |
| | half width (deg) | | | | | | | | | |
| Comparative | 2θ (deg) | 69.1 | 68.4 | 68.1 | 67.4 | 333 | 0.544 | 0.542 | −0.147 | 0.147 |
| Example 1 | Rocking-curve | 0.0075 | 0.0221 | 0.0222 | 0.0223 | | | | | |
| | half width (deg) | | | | | | | | | |
| Comparative | 2θ (deg) | 69.9 | 68.9 | 68.6 | 67.9 | 346 | 0.553 | 0.533 | −1.786 | 1.786 |
| Example 2 | Rocking-curve | 0.0088 | 0.0567 | 0.0788 | 0.1056 | | | | | |
| | half width (deg) | | | | | | | | | |
| Comparative | 2θ (deg) | 69.1 | 68.4 | 68.1 | 67.4 | 338 | 0.544 | 0.542 | −0.166 | 0.166 |
| Example 3 | Rocking-curve | 0.0074 | 0.0219 | 0.0221 | 0.0222 | | | | | |
| | half width (deg) | | | | | | | | | |
| Comparative | 2θ (deg) | 69.9 | 68.9 | 68.6 | 67.9 | 348 | 0.553 | 0.533 | −1.768 | 1.768 |
| Example 4 | Rocking-curve | 0.0086 | 0.0578 | 0.0889 | 0.1092 | | | | | |
| | half width (deg) | | | | | | | | | |

The results shown in Table 1 indicate that the rocking-curve half widths of the 0th peaks in X-ray diffraction measurement of the stacked thin films of Examples 1, 2, and 3 are 0.0076 deg, 0.0075 deg, and 0.0078 deg, respectively, the rocking-curve half widths of the 0th peaks in X-ray diffraction measurement of the stacked thermoelectric thin films of Comparative Examples 1 and 2 are 0.0075 deg and 0.0088 deg, respectively, and these values are substantially the same.

However, with respect to the rocking-curve half widths of the satellite peaks, the rocking-curve half widths of the first-order, second-order, and third-order satellite peaks of Example 1 are 0.0237 deg, 0.0228 deg, and 0.0223 deg, respectively, the rocking-curve half widths of the first-order, second-order, and third-order satellite peaks of Example 2 are 0.0232 deg, 0.0222 deg, and 0.0213 deg, respectively, and the rocking-curve half widths of the first-order, second-order, and third-order satellite peaks of Example 3 are 0.0243 deg, 0.0235 deg, and 0.0234 deg, respectively. On the other hand, the rocking-curve half widths of the first-order, second-order, and third-order satellite peaks of Comparative Example 1 are 0.0221 deg, 0.0222 deg, and 0.0223 deg, respectively, and the rocking-curve half widths of the first-order, second-order, and third-order satellite peaks of Comparative Example 2 are 0.0567 deg, 0.0788 deg, and 0.1056 deg, respectively. Therefore, comparison of crystallinity of the stacked thin film between Examples 1, 2, and 3 and Comparative Examples 1 and 2 reveals that the stacked thin film of Comparative Example 2 has poor crystallinity. Thus, it is found that when as in Comparative Example 2, the Si:Ge composition ratio by atomic number ratio in the SiGe layer 2 is 62:38, it is difficult for the stacked thin film to maintain good crystallinity.

On the other hand, the value of power factor S²σ of Example 1 is 498 (μW/mK²), and the values of power factor S²σ of Examples 2 and 3 are 385 (μW/mK²) and 465 (μW/mK²), respectively, while the values of power factor S²σ of Comparative Examples 1 and 2 are 333 (μW/mK²) and 346 (μW/mK²), respectively. Thus, it is found that when the Si:Ge composition ratio by atomic number ratio in the SiGe layer 2 is within a range of 85:15 to 63:37, a high power factor can be realized.

Further, Table 1 indicates that in Comparative Example 1, the a-axis and c-axis distortion factors of the Si layer 3 are −0.147 and 0.147, respectively, and thus substantially no distortion occurs in the Si layer 3. In contrast, Table 1 indicates that particularly in Examples 1 and 3, the a-axis and c-axis distortion factors of the Si layer 3 are −1.252 and 1.234 and −1.621 and 1.602, respectively, and thus relatively large distortion occurs in the Si layer 3. Thus, it is found that a difference in power factor occurs due to a difference in distortion factor of the Si layer 3, which is caused by a difference in composition of the SiGe layer 2, and a high powder factor can be realized within a composition range of the SiGe layer 2 in which good crystallinity of the stacked thin film can be maintained.

Similarly, the results shown in Table 1 indicate that the rocking-curve half widths of the 0th peaks in X-ray diffraction measurement of the stacked thin films of Examples 4, 5, and 6 are 0.0078 deg, 0.0077 deg, and 0.0079 deg, respectively, the rocking-curve half widths of the 0th peaks in X-ray diffraction measurement of the stacked thin films of Comparative Examples 3 and 4 are 0.0074 deg and 0.0086 deg, respectively, and these values are substantially the same.

However, with respect to the rocking-curve half widths of the satellite peaks, the rocking-curve half widths of the first-order, second-order, and third-order satellite peaks of Example 4 are 0.0468 deg, 0.0679 deg, and 0.0881 deg, respectively, the rocking-curve half widths of the first-order, second-order, and third-order satellite peaks of Example 5 are 0.0465 deg, 0.0576 deg, and 0.0877 deg, respectively, and the rocking-curve half widths of the first-order, second-order, and third-order satellite peaks of Example 6 are 0.0478 deg, 0.0676 deg, and 0.0986 deg, respectively. On the other hand, the rocking-curve half widths of the first-order, second-order, and third-order satellite peaks of Comparative Example1 3 are 0.0219 deg, 0.0221 deg, and 0.0222 deg, respectively, and the rocking-curve half widths of the first-order, second-order, and third-order satellite peaks of Comparative Example 14 are 0.0578 deg, 0.0889 deg, and 0.1092 deg, respectively. Therefore, comparison of crystallinity of the stacked thin film between Examples 4, 5, and 6 and Comparative Examples 3 and 4 reveals that the stacked thin film of Comparative Example 4 has poor crystallinity. Thus, it is found that when as in Comparative Example 4, the Si:Ge composition ratio by atomic number ratio in the SiGe layer 2 is 62:38, it is difficult for the stacked thin film to maintain good crystallinity.

On the other hand, the value of power factor S²σ of Example 4 is 505 (μW/mK²), and the values of power factor S²σ of Examples 5 and 6 are 392 (μW/mK²) and 476 (μW/mK²), respectively, while the value of power factor S²σ of Comparative Example 3 is 338 (μW/mK²) and the value of power factor S²σ of Comparative Example 4 is 348 (μW/mK²). Thus, it is found that when the Si:Ge composition ratio by atomic number ratio in the SiGe layer 2 is within a range of 85:15 to 63:37, a high power factor can be realized.

Further, Table 1 indicates that in Comparative Example 3, the a-axis and c-axis distortion factors of the Si layer 3 are −0.166 and 0.166, respectively, and thus substantially no distortion occurs in the Si layer 3. In contrast, Table 1 indicates that particularly in Examples 4 and 6, the a-axis and c-axis distortion factors of the Si layer 3 are −1.271 and 1.252 and −1.584 and 1.584, respectively, and thus relatively large distortion occurs in the Si layer 3. Thus, it is found that a difference in power factor occurs due to a difference in distortion factor of the Si layer 3, which is caused by a difference in composition of the SiGe layer 2, and a high powder factor can be realized within a composition range of the SiGe layer 2 in which good crystallinity of the stacked thin film can be maintained.

### Example 7

Example 7 was the same as Example 1 except that the thickness of each of the SiGe layer 2 and the Si layer 3 was changed from 0.9 nm to 55 nm, and the value of power factor S²σ in each of the stacked film configurations was confirmed. The results are shown in Table 2. The contents shown in Table 2 reveal that when the thickness of each of the Si layer 3 and the SiGe layer 2 is 1 nm or more and 10 nm or less, a particularly high value of power factor can be achieved.

TABLE 2

| | Si layer (nm) | SiGe layer (nm) | Power factor μW/mK² |
|---|---|---|---|
| Example 7 | 0.9 | 0.9 | 461 |
| | 1 | 1 | 484 |
| | 5 | 5 | 492 |
| | 10 | 10 | 498 |
| | 20 | 20 | 486 |
| | 30 | 30 | 478 |
| | 40 | 40 | 473 |
| | 50 | 50 | 467 |
| | 55 | 55 | 454 |

### Example 8

Example 8 was the same as Example 2 except that the thickness of each of the SiGe layer 2 and the Si layer 3 was changed from 0.9 nm to 55 nm, and the value of power factor S²σ in each of the stacked film configurations was confirmed. The results are shown in Table 3. The contents shown in Table 3 reveal that when the thickness of each of the Si layer 3 and the SiGe layer 2 is 1 nm or more and 10 nm or less, a particularly high value of power factor can be achieved.

TABLE 3

| | Si layer (nm) | SiGe layer (nm) | Power factor μW/mK² |
|---|---|---|---|
| Example 8 | 0.9 | 0.9 | 358 |
| | 1 | 1 | 372 |
| | 5 | 5 | 382 |
| | 10 | 10 | 385 |
| | 20 | 20 | 382 |
| | 30 | 30 | 376 |
| | 40 | 40 | 368 |
| | 50 | 50 | 362 |
| | 55 | 55 | 354 |

### Example 9

Example 9 was the same as Example 3 except that the thickness of each of the SiGe layer 2 and the Si layer 3 was changed from 0.9 nm to 55 nm, and the value of power factor S²σ in each of the stacked film configurations was confirmed. The results are shown in Table 4. The contents shown in Table 4 reveal that when the thickness of each of the Si layer 3 and the SiGe layer 2 is 1 nm or more and 10 nm or less, a particularly high value of power factor can be achieved.

TABLE 4

| | Si layer (nm) | SiGe layer (nm) | Power factor μW/mK² |
|---|---|---|---|
| Example 9 | 0.9 | 0.9 | 402 |
| | 1 | 1 | 414 |
| | 5 | 5 | 446 |
| | 10 | 10 | 465 |
| | 20 | 20 | 454 |
| | 30 | 30 | 442 |
| | 40 | 40 | 424 |
| | 50 | 50 | 412 |
| | 55 | 55 | 397 |

### Example 10

Example 10 was the same as Example 4 except that the thickness of each of the SiGe layer 2 and the Si layer 3 was changed from 0.9 nm to 55 nm, and the value of power factor S²σ in each of the stacked film configurations was confirmed. The results are shown in Table 5. The contents shown in Table 5 reveal that when the thickness of each of the Si layer 3 and the SiGe layer 2 is 1 nm or more and 10 nm or less, a particularly high value of power factor can be achieved.

TABLE 5

| | Si layer (nm) | SiGe layer (nm) | Power factor μW/mK² |
|---|---|---|---|
| Example 10 | 0.9 | 0.9 | 472 |
| | 1 | 1 | 491 |
| | 5 | 5 | 497 |
| | 10 | 10 | 505 |
| | 20 | 20 | 494 |
| | 30 | 30 | 489 |
| | 40 | 40 | 484 |
| | 50 | 50 | 478 |
| | 55 | 55 | 462 |

### Example 11

Example 11 was the same as Example 5 except that the thickness of each of the SiGe layer 2 and the Si layer 3 was changed from 0.9 nm to 55 nm, and the value of power factor S²σ in each of the stacked film configurations was confirmed. The results are shown in Table 6. The contents shown in Table 6 reveal that when the thickness of each of the Si layer 3 and the SiGe layer 2 is 1 nm or more and 10 nm or less, a particularly high value of power factor can be achieved.

TABLE 6

| | Si layer (nm) | SiGe layer (nm) | Power factor μW/mK² |
|---|---|---|---|
| Example 11 | 0.9 | 0.9 | 366 |
| | 1 | 1 | 378 |
| | 5 | 5 | 389 |
| | 10 | 10 | 392 |
| | 20 | 20 | 389 |
| | 30 | 30 | 383 |
| | 40 | 40 | 378 |
| | 50 | 50 | 371 |
| | 55 | 55 | 361 |

### Example 12

Example 12 was the same as Example 6 except that the thickness of each of the SiGe layer 2 and the Si layer 3 was changed from 0.9 nm to 55 nm, and the value of power factor S²σ in each of the stacked film configurations was confirmed. The results are shown in Table 7. The contents shown in Table 7 reveal that when the thickness of each of the Si layer 3 and the SiGe layer 2 is 1 nm or more and 10 nm or less, a particularly high value of power factor can be achieved.

TABLE 7

| | Si layer (nm) | SiGe layer (nm) | Power factor μW/mK² |
|---|---|---|---|
| Example 12 | 0.9 | 0.9 | 408 |
| | 1 | 1 | 421 |
| | 5 | 5 | 458 |
| | 10 | 10 | 476 |
| | 20 | 20 | 468 |
| | 30 | 30 | 453 |
| | 40 | 40 | 436 |
| | 50 | 50 | 421 |
| | 55 | 55 | 406 |

### Example 13

In Example 13, a N-type sample exclusive for thermoelectric evaluation having characteristics equivalent to those of the thermoelectric device 14 having the stacked thin film 15 of the second embodiment was formed and evaluated by using a Sb-doped SiGe layer 2.

The stacked thin film 15 was formed on a substrate 1 after washing with hydrofluoric acid by the same method as in Example 1.

First, the undoped SiGe layer 5 was formed. The thickness of the undoped SiGe layer 5 was 5 nm. The Si:Ge composition ratio by atomic number ratio in the undoped SiGe layer 5 was 70:30. Then, the Si layer 3 was formed in 5 nm on the undoped SiGe layer 5, and next the SiGe layer 2 was formed in 5 nm. The Si:Ge composition ratio by atomic number ratio in the SiGe layer 2 was 70:30. Sb was added at the same time as the deposition of the SiGe layer 2. The amount of Sb added was 0.001 atomic % based on SiGe.

Then, the Si layer 3 was formed in 5 nm. A stacked layer structure 6 including the undoped SiGe layer 5, the Si layer 3, the SiGe layer 2, and the Si layer 3 was deposited repeatedly 10 times, thereby forming the stacked thin film 15 including multiple layers formed by stacking 10 times the stacked layer structure 6.

### Example 14

In Example 14, the Si:Ge composition ratio by atomic number ratio in the undoped SiGe layer 5 and the SiGe layer 2 of Example 13 was changed to 85:15. Excepting the composition ratio, Example 14 was the same as Example 13.

### Example 15

In Example 15, the Si:Ge composition ratio by atomic number ratio in the undoped SiGe layer 5 and the SiGe layer 2 of Example 13 was changed to 63:37. Excepting the composition ratio, Example 15 was the same as Example 13.

### Example 16

Although, in Example 13, the SiGe layer 2 was formed by adding Sb to SiGe, in Example 16, a P-type sample exclusive for thermoelectric evaluation was formed and evaluated by using B in place of Sb. Excepting the additive, Example 16 was the same as Example 13.

### Example 17

Although, in Example 14, the SiGe layer 2 was formed by adding Sb to SiGe, in Example 17, a P-type sample exclusive for thermoelectric evaluation was formed and evaluated by using B in place of Sb. Excepting the additive, Example 17 was the same as Example 14.

### Example 18

Although, in Example 15, the SiGe layer 2 was formed by adding Sb to SiGe, in Example 18, a P-type sample exclusive for thermoelectric evaluation was formed and evaluated by using B in place of Sb. Excepting the additive, Example 18 was the same as Example 15.

In Examples 13, 14, 15, 16, 17, and 18, the sample for evaluation was formed and the Seebeck coefficient was measured as in Example 1. The results of power factor of Examples 13, 14, 15, 16, 17, and 18 are shown in Table 8.

TABLE 8

| | Power factor (μW/mK²) |
|---|---|
| Example13 | 502 |
| Example14 | 393 |
| Example15 | 472 |
| Example16 | 508 |
| Example17 | 396 |
| Example18 | 481 |

The results shown in Table 8 indicate that the values of power factor S²σ in Examples 13, 14, 15, 16, 17, and 18 are 502, 393, 472, 508, 396, and 481 (μW/mK²), respectively. Thus, it is found that when the Si:Ge composition ratio by atomic number ratio in the undoped SiGe layer 5 and the SiGe layer 2 is within a range of 85:15 to 63:37, a high power factor value can be realized by the stacked thin film 15 of the second embodiment.

What is claimed is:

1. A thermoelectric device comprising:
a semiconductor stacked thin film including a SiGe layer and a Si layer in contact with the SiGe layer, wherein the SiGe has a Si:Ge composition ratio by atomic number ratio within a range of 85:15 to 63:37; and the stacked thin film has a plurality of stacked structures each having the SiGe layer and the Si layer.

2. The thermoelectric device according to claim 1, wherein the SiGe layer is in contact with each of both surfaces of the Si layer.

3. The thermoelectric device according to claim 1, wherein an additive of a group XIII element or group XV element is added to at least one of the SiGe layers in the plurality of stacked structures.

4. The thermoelectric device according to claim 1, wherein at least one of the rocking-curve half widths of a 0th order peak and satellite peaks thereof corresponding to the average lattice constant of the superlattice of the stacked thin film observed by X-ray diffraction measurement is 0.1° or less.

5. The thermoelectric device according to claim 1, wherein in X-ray diffraction measurement of the stacked thin film, third or higher-order satellite peaks due to the superlattice of the stacked thin film are observed.

6. The thermoelectric device according to claim 1, wherein each of the Si layer and the SiGe layer has a thickness of 1 nm or more and 10 nm or less.
